(19) United States
(12) Patent Application Publication
(10) Pub. No.: US 2017/0127533 A1
(43) Pub. Date: May 4, 2017

(54) PRODUCTION PROCESS FOR SOLDER ELECTRODE, PRODUCTION PROCESS FOR LAMINATE, LAMINATE AND ELECTRONIC PART

(71) Applicant: JSR CORPORATION, Tokyo (JP)

(72) Inventors: JUN MUKAWA, Tokyo (JP); SEIICHIROU TAKAHASHI, Tokyo (JP); KOUICHI HASEGAWA, Tokyo (JP); KATSUMI INOMATA, Tokyo (JP)

(73) Assignee: JSR CORPORATION, Tokyo (JP)

(21) Appl. No.: 15/375,176

(22) Filed: Dec. 12, 2016

Related U.S. Application Data
(63) Continuation-in-part of application No. PCT/JP2015/067013, filed on Jun. 12, 2015.

(30) Foreign Application Priority Data
Jun. 20, 2014 (JP) 2014-127018

(51) Int. Cl. H05K 3/40; H05K 3/34; H05K 3/06; G03F 7/30; B23K 35/02; G03F 7/16; G03F 7/20; H05K 1/11; H05K 3/36

(52) U.S. Cl. CPC H05K 3/4007; H05K 1/111; H05K 3/3468; H05K 3/064; H05K 3/368; H05K 3/3431; B23K 35/0244; G03F 7/162; G03F 7/20; G03F 7/30; B23K 2201/42

(57) ABSTRACT

A production process for a solder electrode, including: a step (I) of forming an opening in a portion of a film provided on a substrate having an electrode pad, the portion corresponding to the electrode pad on the substrate, and thereby forming a resist from the film on the substrate, and a step (II) of filling the opening of the resist with molten solder, wherein the resist is composed of at least two layers each containing a resin as a constituent, and a layer (1) of the resist, the layer (1) being closest to the substrate, does not substantially contain a component that thermally crosslinks the resin contained as a constituent in the layer (1) and a component that undergoes thermal self-crosslinking.

### CROSS-REFERENCE TO RELATED APPLICATIONS

This application is a continuation-in-part application of PCT Application no. PCT/JP2015/067013, filed on Jun. 12, 2015, which claims the priority benefit of Japan Application no. 2014-127018, filed on Jun. 20, 2014. The entirety of each of the above-mentioned patent applications is hereby incorporated by reference herein and made a part of this specification.

### TECHNICAL FIELD

The present invention relates to a production process for a solder electrode, a production process for a laminate, a laminate, and an electronic part.

### BACKGROUND ART

An IMS (injection molded solder) method is one method to form a solder pattern (solder bumps). As methods to form a solder pattern on a substrate such as wafer, a solder paste method, and a plating method, etc. have been used so far. In these methods, however, control of a height of a solder bump is difficult, and in addition, there are restrictions such as that the solder composition cannot be selected freely. On the other hand, the IMS method is known to be free from these restrictions.

As shown in Patent literatures 1 to 4, the IMS method is a method characterized in that molten solder is injected between resist patterns while bringing a nozzle capable of injection molding into close contact with the resist.

### CITATION LIST

### Patent Literature

Patent literature 1: Japanese Patent Laid-Open Publication No. 1994-055260

Patent literature 2: Japanese Patent Laid-Open Publication No. 2007-294954

Patent literature 3: Japanese Patent Laid-Open Publication No. 2007-294959

Patent literature 4: Japanese Unexamined Patent Application Publication (Translation of PCT Application) No. 2013-520011

### SUMMARY OF INVENTION

In the IMS method, it is necessary to heat a nozzle at a high temperature of about 150 to 250° C. in order to melt solder, and therefore, the resist comes into close contact with a nozzle of a high temperature. On this account, there is a problem that because of damage done to the resist by the high temperature, adhesion between a substrate and the resist is lowered particularly in the injection molding of molten solder, and a desired pattern cannot be obtained.

The present invention provides a production process for a solder electrode, in which even if a method accompanied by a high-temperature treatment, such as IMS method, is used, damage done to a resist is small and adhesion particularly between a substrate and a resist is excellent.

A first embodiment of the production process for a solder electrode according to the present invention is a production process for a solder electrode, comprising: a step (I) of forming an opening in a portion of a film provided on a substrate having an electrode pad, said portion corresponding to the electrode pad on the substrate, and thereby forming a resist from the film on the substrate, and a step (II) of filling the opening of the resist with molten solder, wherein the resist is composed of at least two layers each containing a resin as a constituent, and a layer (1) of the resist, said layer (1) being closest to the substrate, does not substantially contain a component that thermally crosslinks the resin contained as a constituent in the layer (1) and a component that undergoes thermal self-crosslinking.

In the above production process for a solder electrode, a layer (2) in the resist, said layer (2) being farthest from the substrate, preferably contains at least one component selected from a component that thermally crosslinks the resin contained as a constituent in the layer (2) and a component that undergoes thermal self-crosslinking.

In the above production process for a solder electrode, the thickness of the layer (1) of the resist, said layer (1) being closest to the substrate, is preferably 0.001 to 0.9 time the thickness of the resist.

A second embodiment of the production process for a solder electrode according to the present invention is a production process for a solder electrode, comprising: a step (I), having a step (I-1) of forming a coating film (a1) obtained from a resin composition on a substrate having an electrode pad, a step (I-2) of forming a coating film (a2) obtained from a photosensitive resin composition on the coating film (a1) to form a film including the coating film (a1) and the coating film (a2), a step (I-3) of selectively exposing the film to light in such a manner that an opening is formed in a portion of the film, said portion corresponding to the electrode pad on the substrate, and a step (I-4) of developing the film to form an opening in a portion of the film, said portion corresponding to the electrode pad on the substrate, and thereby forming a resist from the film on the substrate; and a step (II) of filling the opening of the resist with molten solder,

wherein the resin composition does not substantially contain a component that thermally crosslinks a resin contained in the resin composition and a component that undergoes thermal self-crosslinking, and the photosensitive resin composition contains at least one component selected from a component that thermally crosslinks a resin contained in the photosensitive resin composition and a component that undergoes thermal self-crosslinking.

In the above production process for a solder electrode, a step (III) of peeling the resist can be carried out after the step (II).

The electronic part of the present invention has a solder electrode formed by the above production process for a solder electrode.

A first production process for a laminate according to the present invention is a production process for a laminate, comprising a step (I) of forming an opening in a portion of a film provided on a first substrate having an electrode pad, said portion corresponding to the electrode pad on the substrate, and thereby forming a resist from the film on the substrate, a step (II) of filling the opening of the resist with molten solder to produce a solder electrode, and a step (IV) of laminating a second substrate having an electrode pad on the first substrate in such a manner that an electrical connection structure is formed between the electrode pad of the first substrate and the electrode pad of the second substrate through the solder electrode,

wherein the resist is composed of at least two layers each containing a resin as a constituent, and a layer (1) of the resist, said layer (1) being closest to the first substrate, does not substantially contain a component that thermally crosslinks the resin contained as a constituent in the layer (1) and a component that undergoes thermal self-crosslinking.

A second production process for a laminate according to the present invention is a production process for a laminate, comprising: a step (I) of forming an opening in a portion of a film provided on a first substrate having an electrode pad, said portion corresponding to the electrode pad on the substrate, and thereby forming a resist from the film on the substrate, a step (II) of filling the opening of the resist with molten solder to produce a solder electrode, a step (III) of peeling the resist from the first substrate, and a step (IV) of laminating a second substrate having an electrode pad on the first substrate in such a manner that an electrical connection structure is formed between the electrode pad of the first substrate and the electrode pad of the second substrate through the solder electrode,

wherein the resist is composed of at least two layers each containing a resin as a constituent, and a layer (1) of the resist, said layer (1) being closest to the first substrate, does not substantially contain a component that thermally crosslinks the resin contained as a constituent in the layer (1) and a component that undergoes thermal self-crosslinking.

The laminate of the present invention is produced by the above production process for a laminate.

The electronic part of the present invention has the above laminate.

According to the production process for a solder electrode of the present invention, damage done to the resist is small, excellent adhesion between the substrate and the resist can be maintained and a desired solder electrode can be surely formed, even if a method accompanied by a high-temperature treatment is used. The production process for a solder electrode of the present invention can be effectively used for bump formation based on an IMS method, or the like.

### BRIEF DESCRIPTION OF DRAWINGS

FIG. 1 is a partially sectional view of a resist holding substrate 13 that is one specific example of a resist holding substrate in the present invention.

FIG. 2 is a schematic explanatory view showing an operation of a pin test that is an adhesion evaluation test used in the working examples.

FIGS. 3A and 3B are each a schematic sectional view of a laminate according to the present invention.

FIG. 4 is an electron microscopic image of solder electrodes produced in Example 1.

FIG. 5 is an electron microscopic image of solder electrodes produced in Comparative Example 2.

### DESCRIPTION OF EMBODIMENTS

The production process for a solder electrode according to the present invention is a production process for a solder electrode, which comprises: a step (I) of forming an opening in a portion of a film provided on a substrate having an electrode pad, said portion corresponding to the electrode pad on the substrate, and thereby forming a resist from the film on the substrate, and a step (II) of filling the opening of the resist with molten solder, and is characterized in that the resist is composed of at least two layers each containing a resin as a constituent, and a layer (1) of the resist, said layer (1) being closest to the substrate, does not substantially contain a component that thermally crosslinks the resin contained as a constituent in the layer (1) and a component that undergoes thermal self-crosslinking.

The step (I) and the step (II) included in the production process for a solder electrode according to the present invention are steps included in a production process for a solder electrode used for usual bump formation based on an IMS method, or the like. The production process for a solder electrode according to the present invention is an invention in which a resist used in a conventional production process for a solder electrode has been made to have specific structure and composition.

In the step (1), an opening is formed in a portion of a film provided on a substrate having an electrode pad, said portion corresponding to the electrode pad on the substrate. The substrate is, for example, a semiconductor substrate, a glass substrate, a silicon substrate, or a substrate obtained by providing any of various metal films on a surface of a semiconductor plate, a glass plate, or a silicon plate. The substrate has a large number of electrode pads.

The film is a coating film obtained by applying such a film-forming composition as described later onto a substrate, or the like. The portion of the film that corresponds to the electrode pad on the substrate is a portion of the film that is located above an area including the electrode pad on the upper surface of the substrate. For one electrode pad, one portion corresponding to the electrode pad is determined.

The opening is a void or a hole reaching from the upper surface of the film to the lower surface thereof. By forming an opening in the film, the film becomes a resist, and a resist having an opening is formed on the substrate. There is formed a state where a resist is present only above an area other than the area including the electrode pad on the upper surface of the substrate and no resist is present above the area including the electrode pad on the upper surface of the substrate. Electrode pads on the substrate are usually provided like a pattern, and therefore, the openings are also formed like a pattern. In the present invention, a structure constituted of the substrate and the resist is sometimes referred to as a resist holding substrate.

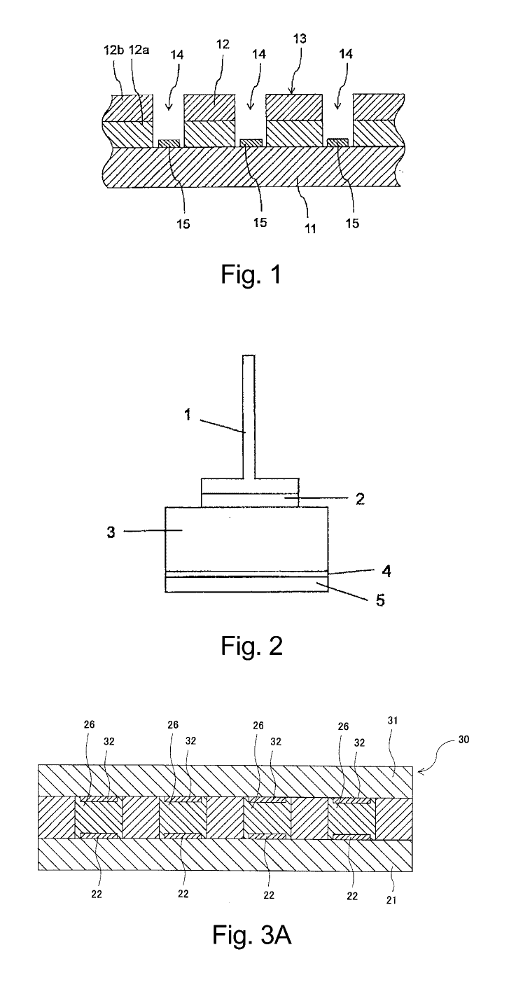

In FIG. 1, a partially sectional view of a resist holding substrate 13 that is one specific example of a resist holding substrate in the present invention is shown. The resist holding substrate 13 has a resist 12 on a substrate 11, and the resist 12 has an opening 14 at a portion corresponding to an electrode pad 15 on the substrate 11.

In the step (II), the opening is filled with molten solder. The molten solder is obtained by heating solder for use in soldering of the substrate to not lower than its melting point, and the type of the solder is not specifically restricted. The method to fill the opening with the molten solder is not specifically restricted, and for example, an IMS method can be used. By injecting the molten solder into the opening, the space above the area including the electrode pad on the upper surface of the substrate is filled with the molten solder. By cooling the molten solder contained in the opening, a solder electrode is produced. In FIG. 1, by filling each opening 14 of the resist holding substrate 13 with molten solder, the molten solder is placed on each electrode pad 15, and by cooling this molten solder, a solder electrode is formed.

In the above production process for a solder electrode, a step (III) of peeling the resist may be carried out after the step (II).

The resist for use in the production process for a solder electrode is composed of at least two layers each containing a resin as a constituent, and a layer (1) of the resist, said layer (1) being closest to the substrate, does not substantially contain a component that thermally crosslinks the resin contained as a constituent in the layer (1) and a component that undergoes thermal self-crosslinking.

As previously described, in the IMS method, the resist comes into close contact with a nozzle of a high temperature, and therefore, there is a problem that the resist is damaged by heat, and adhesion between the substrate and the resist is lowered, so that a desired solder pattern such as solder electrodes cannot be obtained. The present inventor has found that one cause of lowering of adhesion between the substrate and the resist due to the heat is that a component, which is present in the resist and undergoes thermal crosslinking reaction, is crosslinked with the resin in the resist or undergoes self-crosslinking when the resist is exposed to a high temperature, and as a result, the resist shrinks. That is to say, referring to FIG. 1, it is presumed that when the resist 12 is exposed to a high temperature, a component, which is present in the resist 12 and undergoes crosslinking reaction, crosslinks the resin or undergoes self-crosslinking to shrink the resist 12, the resist 12 partially peels off from the substrate 11 to form a gap between the resist 12 and the substrate 11, this gap joins the opening 14, the molten solder contained in the opening 14 leaks out into the gap, and the molten solder adheres to the substrate 11 beyond the soldering area, so that the solder pattern is broken.

By using a resist comprising, as the closest layer to the substrate, the layer (1) which does not substantially contain a component that thermally crosslinks the resin contained as a constituent in the layer (1) and a component that undergoes thermal self-crosslinking, shrinkage of the layer (1) based on the crosslinking of the resin in the layer (1) that is in contact with the substrate or based on the self-crosslinking is prevented. As a result, adhesion between the substrate and the resist is maintained, and peeling of the resist from the substrate is inhibited. Consequently, obtaining of a desired solder electrode with good reproducibility has been succeeded.

The resist contains a resin as a constituent. The resist is a laminate composed of at least two layers. The number of layers is not specifically restricted, and any of two layers, three layers, four layer, etc. are available, but in usual, two layers are enough. The thickness of the resist is not specifically restricted, and the thickness may be the same as a thickness of a resist used for usual bump formation or the like. In usual, the thickness of the resist is 1 to 500 μm. Each layer of the resist is usually formed from a resin composition, and coating films formed from resin compositions are laminated successively on the substrate to form a film, and then an opening is provided in the film, whereby a resist is formed. The resist 12 contained in the resist holding substrate 13 shown in FIG. 1 is composed of two layers, and has a layer (1) 12a closest to the substrate and a layer (2) 12b farthest from the substrate.

Of the layers contained in the resist, the layer (1) closest to the substrate is formed from, for example, the later-described resin composition.

The layer (1) does not substantially contain a component that thermally crosslinks a resin contained as a constituent in the layer (1) and a component that undergoes thermal self-crosslinking. The component that thermally crosslinks a resin and the component that undergoes thermal self-crosslinking are a component having a function to thermally crosslink a resin and a component undergoing thermal self-crosslinking, respectively, and they are both so-called crosslinking agents. The expression “does not substantially contain” means that the content of the component is an amount which does not cause such shrinkage of the layer (1) attributable to crosslinking of a resin or self-crosslinking as brings about peeling of the layer from the substrate. Since the amount which does not cause such shrinkage of the layer (1) attributable to crosslinking of a resin or self-crosslinking as brings about peeling of the layer from the substrate depends upon the types of the resin and the component that crosslinks the resin, etc., it cannot be determined uniquely, but it is usually not more than 0.1% by mass based on 100% by mass of all the solid components contained in the resin composition.

The resin contained in the layer (1) as a constituent is, for example, a resin contained in a coating film (a1) formed from the later-described resin composition.

The thickness of the layer (1) is preferably 0.001 to 0.9 time, more preferably 0.05 to 0.5 time, still more preferably 0.01 to 0.1 time, the thickness of the resist. When the thickness of the layer (1) satisfies this condition, excellent adhesion between the substrate and the resist can be maintained, so that such a thickness is preferable.

Of the layers contained in the resist, layers other than the layer (1) closest to the substrate may contain a component that thermally crosslinks a resin contained as a constituent in these layers or the layer (1), or a component that undergoes thermal self-crosslinking. The reason is that if the layer (1) closest to the substrate, that is, a layer in contact with the substrate, does not substantially contain a component that thermally crosslinks a resin contained as a constituent in the layer (1) and a component that undergoes thermal self-crosslinking, lowering of adhesion between the substrate and the resist attributable to shrinkage of the resist based on crosslinking of the resin or self-crosslinking can be prevented.

The layer (2) farthest from the substrate in the resist, that is, a layer that forms a surface on the opposite side to the surface formed by the layer (1) in the resist, preferably contains at least one component (also referred to a “crosslinking agent” hereinafter) selected from a component that thermally crosslinks a resin contained as a constituent in the layer (2) and a component that undergoes thermal self-crosslinking. If the layer (2) does not contain a crosslinking agent, the layer (2) is deformed when heat is applied to the resist from an IMS head as in the IMS method, so that a desired solder electrode is not obtained in some cases. If the layer (2) contains a crosslinking agent, crosslinking reaction of the resin or self-crosslinking takes place in the layer (2) when heat is applied from an IMS head, whereby the layer (2) is strengthened and can withstand heat from the IMS head, so that obtaining of a desired solder electrode becomes easier. The crosslinking agent contained in the layer (2) is usually present in the layer (2) as a residual component that has not taken part in crosslinking when the layer (2) is formed using a resin composition containing the crosslinking agent.

The amount of the crosslinking agent contained in the layer (2) has only to be such an amount that the resin contained in the layer (2) can be crosslinked to thereby strengthen the layer (2) to the extent that a desired solder electrode can be obtained, but such an amount depends upon the types of the resin and the component to crosslink the resin, so that it cannot be determined uniquely.

The resin contained as a constituent in the layer (2) is, for example, a resin contained in a coating film (a2) formed from the later-described photosensitive resin composition. The crosslinking agent contained in the layer (2) is, for example, at least one component selected from a component that thermally crosslinks a resin contained in, for example, the later-described photosensitive resin composition and a component that undergoes thermal self-crosslinking.

As an embodiment of the production process for a solder electrode according to the present invention, there can be mentioned a production process for a solder electrode, comprising: a step (I), having a step (I-1) of forming a coating film (a1) obtained from a resin composition on a substrate having an electrode pad, a step (I-2) of forming a coating film (a2) obtained from a photosensitive resin composition on the coating film (a1) to form a film including the coating film (a1) and the coating film (a2), a step (I-3) of selectively exposing the film to light in such a manner that an opening is formed in a portion of the film, said portion corresponding to the electrode pad on the substrate, and a step (I-4) of developing the film to form an opening in an area of the film, said area corresponding to the electrode pad on the substrate, and thereby forming a resist from the film on the substrate; and a step (II) of filling the opening of the resist with molten solder, wherein the resin composition does not substantially contain a component that thermally crosslinks a resin contained in the resin composition and a component that undergoes thermal self-crosslinking, and the photosensitive resin composition contains at least one component selected from a component that thermally crosslinks a resin contained in the photosensitive resin composition and a component that undergoes thermal self-crosslinking.

The resin composition for use in the step (I-1) does not substantially contain a component that thermally crosslinks a resin (also referred to as a “resin (1)” hereinafter) contained in the resin composition and a component that undergoes thermal self-crosslinking (both components being together also referred to as a “crosslinking component (1)” hereinafter). The resin (1) is not specifically restricted as long as it is a resin capable of forming a resist, but a resin insoluble in a solvent contained in a composition used for forming a coating film provided in contact with the coating film (a1) is selected. For example, when a coating film (a2) is provided in contact with the coating film (a1), a resin insoluble in a solvent contained in a composition used for forming the coating film (a2) is selected as the resin (1).

As the resin (1), a resin used for a resist that is used in usual bump formation or the like can be used. As such a resin, a resin described in, for example, Japanese Patent Application No. 2005-266795 can be mentioned, and examples of such resins include resins obtained by (co)polymerizing amide-based monomers, such as N-(p-hydroxyphenyl)acrylamide, N-(p-hydroxyphenyl)methacrylamide, N-(p-hydroxybenzyl)acrylamide, N-(p-hydroxybenzyl)methacrylamide, N-(3,5-dimethyl-4-hydroxybenzyl)acrylamide, N-(3,5-dimethyl-4-hydroxybenzyl)methacrylamide, N-(3,5-tert-butyl-4-hydroxybenzyl)acrylamide and N-(3,5-tert-butyl-4-hydroxybenzyl)methacrylamide. By the use of a resin obtained by (co)polymerizing the amide-based monomer, a coating film (a1) slightly soluble in a solvent usually contained in a photosensitive resin composition used for forming the coating film (a2) can be formed. The content of the resin (1) in solid components of the resin composition used in the step (I-1) is usually not less than 50% by mass, preferably not less than 90% by mass.

This resin composition appropriately contains a polymerization inhibitor, a solvent, a surface active agent, an adhesive aid, or an inorganic filler, etc., in addition to the resin (1).

As the method to form the coating film (a1), a method comprising applying the resin composition to the substrate and heating the applied resin composition to dryness can be mentioned. The method to apply the resin composition is not specifically restricted, and examples of the methods include spraying method, roll coating method, spin coating method, slit die coating method, bar coating method and inkjet method. The film thickness of the coating film (a1) is preferably 0.001 to 10 μm, more preferably 0.01 to 5 μm, still more preferably 0.1 to 1 μm. In the case where the coating film (a1) is formed from a non-photosensitive resin composition and the coating film (a2) is formed from a photosensitive resin composition, formation of such a thin film as above as the coating film (a1) makes it possible to develop the coating film (a1) simultaneously with development of the coating film (a2). Moreover, when the coating film (a1) has the above thickness, the layer (1) formed from the coating film (a1) is easily adjusted to the aforesaid thickness.

The resin contained in the coating film (a1) is a resin contained as a constituent in the aforesaid layer (1).

The photosensitive resin composition for use in the step (I-2) contains at least one component selected from a component that thermally crosslinks a resin (also referred to as a “resin (2)” hereinafter) contained in the photosensitive resin composition and a component that undergoes thermal self-crosslinking (both components being together also referred to as a “crosslinking component (2)” hereinafter), and a photoresponsive compound. The resin (2) is not specifically restricted as long as it is a resin capable of forming a resist, and a resin such as an alkali-soluble resin used for a resist that is used in usual bump formation is enough. Examples of such resins include resins obtained by polymerization using, as a part of raw material monomers, a hydroxyl group-containing aromatic vinyl compound (also referred to as a “monomer (1)” hereinafter) such as o-hydroxystyrene, m-hydroxystyrene, p-hydroxystyrene or p-isopropenylphenol. Moreover, a resin obtained by copolymerizing the monomer (1) and another monomer (also referred to as a “monomer (2) hereinafter) capable of being copolymerized with the monomer (1), or the like can be also mentioned.

Examples of the monomers (2) include aromatic vinyl compounds, such as styrene, α-methylstyrene, p-methylstyrene and p-methoxystyrene; hetero atom-containing alicyclic vinyl compounds, such as N-vinylpyrrolidone and N-vinylcaprolactam; (meth)acrylic acid derivatives having glycol structure, such as phenoxydiethylene glycol (meth)acrylate, phenoxytriethylene glycol (meth)acrylate, phenoxytetraethylene glycol (meth)acrylate, phenoxypolyethylene glycol (meth)acrylate, phenoxydipropylene glycol (meth)acrylate, phenoxytripropylene glycol (meth)acrylate, phenoxytetrapropylene glycol (meth)acrylate, lauroxydiethylene glycol (meth)acrylate, lauroxytriethylene glycol (meth)acrylate, lauroxytetraethylene glycol (meth)acrylate, lauroxydipropylene glycol (meth)acrylate, lauroxytripropylene glycol (meth)acrylate and lauroxytetrapropylene glycol (meth)acrylate; cyano group-containing vinyl compounds, such as acrylonitrile and methacrylonitrile; conjugated diolefins, such as 1,3-butadiene and isoprene; carboxyl group-containing vinyl compounds, such as acrylic acid and methacrylic acid; (meth)acrylic esters, such as methyl (meth)acrylate, ethyl (meth)acrylate, n-propyl (meth)acrylate, n-butyl (meth)acrylate, 2-hydroxyethyl (meth)acrylate, 2-hydropropyl (meth)acrylate, polyethylene glycol mono (meth)acrylate, polypropylene glycol mono (meth)acrylate, glycerol mono (meth)acrylate, phenyl (meth)acrylate, benzyl (meth)acrylate, cyclohexyl (meth)acrylate, isobornyl (meth)acrylate and tricyclodecanyl (meth)acrylate; and p-hydroxyphenyl(meth)acrylamide.

The crosslinking component (2) is not specifically restricted, and is appropriately determined according to the type of the resin (2), and the like. In the case where the resin (2) is a resin obtained by polymerizing the monomer (1) or a resin obtained by copolymerizing the monomer (1) and the monomer (2), examples of the crosslinking components (2) include: melamine-based crosslinking agents, such as polymethylolated melamine, hexamethoxymethylmelamine, hexaethoxymethylmelamine, hexapropoxymethylmelamine and hexabutoxymethylmelamine; glycoluril-based crosslinking agents, such as polymethylolated glycoluril, tetramethoxymethylglycoluril and tetrabutoxymethylglycoluril; methylol group-containing compounds, such as 2,6-dimethoxymethyl-4-t-butylphenol, 2,6-dimethoxymethyl-p-cresol and 2,6-diacetoxymethyl-p-cresol; oxirane ring-containing compounds, such as resorcinol diglycidyl ether, pentaerythritol glycidyl ether, trimethylolpropane polyglycidyl ether, glycerol polyglycidyl ether, phenyl glycidyl ether, neopentyl glycol diglycidyl ether, ethylene/polyethylene glycol diglycidyl ether, propylene/polypropylene glycol diglycidyl ether, 1,6-hexanediol diglycidyl ether, sorbitol polyglycidyl ether, propylene glycol diglycidyl ether and trimethylolpropane triglycidyl ether; monofunctional (meth)acrylate compounds, such as 2-hydroxyethyl (meth)acrylate, 2-hydroxypropyl (meth)acrylate, and 2-hydroxybutyl (meth)acrylate; methyl (meth)acrylate, ethyl (meth)acrylate, propyl (meth)acrylate, isopropyl (meth)acrylate, butyl (meth)acrylate, isobutyl (meth)acrylate, tert-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecylamyl (meth)acrylate, lauryl (meth)acrylate, octadecyl (meth)acrylate, stearyl (meth)acrylate; tetrahydrofurfuryl (meth)acrylate, benzyl (meth)acrylate, phenoxyethyl (meth)acrylate, ethoxyethyl (meth)acrylate, butoxyethyl (meth)acrylate, and glycerol (meth)acrylate; ethylene glycol monomethyl ether (meth)acrylate, ethylene glycol monoethyl ether (meth)acrylate, polyethylene glycol mono(meth)acrylate, polypropylene glycol mono(meth)acrylate, methoxyethylene glycol (meth)acrylate, ethoxydiethylene glycol (meth)acrylate, methoxypolyethylene glycol (meth)acrylate, methoxypolypropylene glycol (meth)acrylate, phenoxypolyethylene glycol (meth)acrylate, and phenoxypolypropylene glycol (meth)acrylate; tricycle[5.2.1.0^{2,6}]decadienyl (meth)acrylate, tricycle[5.2.1.0^{2,6}]decanyl (meth)acrylate, tricycle[5.2.1.0^{2,6}]decenyl (meth)acrylate, isobornyl (meth)acrylate, bornyl (meth)acrylate, and cyclohexyl (meth)acrylate; acrylic acid amide, methacrylic acid amide, diacetone (meth)acrylamide, isobutoxymethyl (meth)acrylamide, N,N-dimethyl (meth)acrylamide, tert-octyl(meth)acrylamide, dimethylaminoethyl (meth)acrylate, diethylaminoethyl (meth)acrylate, and 7-amino-3,7-dimethyloctyl (meth)acrylate; and polyfunctional (meth)acrylate compounds, such as trimethylolpropane di(meth)acrylate, trimethylolpropane tri(meth)acrylate, trimethylolpropane PO (propylene oxide) modified tri(meth)acrylate, tetramethylolpropane tetra(meth)acrylate, ethylene glycol di(meth)acrylate, tetraethylene glycol di(meth)acrylate, polyethylene glycol di(meth)acrylate, 1,4-butanediol di(meth)acrylate, 1,6-hexanediol di(meth)acrylate, propylene glycol di(meth)acrylate, butylene glycol di(meth)acrylate, neopentyl glycol di(meth)acrylate, tris(2-hydroxyethyl)isocyanurate di(meth)acrylate, tris(2-hydroxyethyl)isocyanurate tri(meth)acrylate, tricyclodecane dimethanol di(meth)acrylate, epoxy (meth)acrylate obtained by addition of (meth)acrylic acid to diglycidyl ether of bisphenol A, bisphenol A di(meth)acryloyloxyethyl ether, bisphenol A di(meth)acryloyloxymethylethyl ether, bisphenol A di(meth)acryloyloxyethyloxyethyl ether, pentaerythritol tri(meth)acrylate, pentaerythritol tetra(meth)acrylate, dipentaerythritol penta(meth)acrylate, and polyester (meth)acrylate (tri- or higher functional).

As the crosslinking component (2), a commercially available compound can be used as it is. Examples of the commercial available compounds include ARONIX M-210, ARONIX M-309, ARONIX M-310, ARONIX M-320, ARONIX M-400, ARONIX M-7100, ARONIX M-8030, ARONIX M-8060, ARONIX M-8100, ARONIX M-9050, ARONIX M-240, ARONIX M-245, ARONIX M-6100, ARONIX M-6200, ARONIX M-6250, ARONIX M-6300, ARONIX M-6400 and ARONIX M-6500 (all available from Toagosei Co., Ltd.); KAYARAD R-551, KAYARAD R-712, KAYARAD TMPTA, KAYARAD HDDA, KAYARAD TPGDA, KAYARAD PEG400DA, KAYARAD MANDA, KAYARAD HX-220, KAYARAD HX-620, KAYARAD R-604, KAYARAD DPCA-20, KAYARAD DPCA-30, KAYARAD DPCA-60 and KAYARAD DPCA-120 (all available from Nippon Kayaku Co., Ltd.); and VISCOAT #295, VISCOAT 300, VISCOAT 260, VISCOAT 312, VISCOAT 335HP, VISCOAT 360, VISCOAT GPT, VISCOAT 3PA and VISCOAT 400 (all available from Osaka Organic Chemical Industry Ltd.)

The content of the crosslinking component (2) in the photosensitive resin composition is preferably such an amount that when the crosslinking component (2) crosslinks the resin (2) or undergoes self-crosslinking to form the coating film (a2), the crosslinking component (2) remains in the coating film (2). If the content is such an amount, the layer (2) contains a component that thermally crosslinks the resin contained as a constituent in the layer (2), and when heat is applied from an IMS head, crosslinking reaction of the resin or self-crosslinking takes place in the layer (2), so that the layer (2) is strengthened, as previously described. The residue is preferably 40 to 80% by mass, more preferably 50 to 70% by mass, when the amount of the crosslinking component (2) used in the photosensitive resin composition is 100% by mass. The residue is an amount measured by an IR spectrum.

Examples of the photoresponsive compounds include a photoacid generator and a photoradical polymerization initiator.

Examples of the photoacid generators include onium salt compounds, such as diphenyliodonium trifluoromethanesulfonate, diphenyliodonium p-toluenesulfonate and triphenylsulfonium trifluoromethanesulfonate; 1,1-bis(4-chlorophenyl)-2,2,2-trichloroethane; s-triazine derivatives, such as phenyl-bis(trichloromethyl)-s-triazine; sulfone compounds, such as 4-trisphenacylsulfone and mesitylphenacylsulfone; sulfonic acid compounds, such as benzoin tosylate and o-nitrobenzyl p-toluenesulfonate; and sulfonimide compounds, such as N-(trifluoromethylsulfonyloxy)succinimide and N-(trifluoromethylsulfonyloxy)phthalimide.

Examples of the photoradical polymerization initiators include biimidazole compounds, such as 2,2′-bis(2,4-dichlorophenyl)-4,5,4′,5′-tetraphenyl-1,2′-biimidazole, 2,2′-bis(2-chlorophenyl)-4,5,4′,5′-tetraphenyl-1,2′-biimidazole, 2,2′-bis(2,4-dichlorophenyl)-4,5,4′,5′-tetraphenyl-1,2′-biimidazole, 2,2′-bis(2,4-dimethylphenyl)-4,5,4′,5′-tetraphenyl-1,2′-biimidazole, 2,2′-bis(2-methylphenyl)-4,5,4′,5′-tetraphenyl-1,2′-biimidazole and 2,2′-diphenyl-4,5,4′,5′-tetraphenyl-1,2′-biimidazole; phenone compounds, such as diethoxyacetophenone and 2-(4-methylbenzyl)-2-dimethylamino-1-(4-morpholinophenyl)butanone; acylphosphine oxide compounds, such as 2,4,6-trimethylbenzoyldiphenylphosphine oxide; triazine compounds, such as 2,4-bis(trichloromethyl)-6-(4-methoxyphenyl)-1,3,5-triazine and 2,4-bis(trichloromethyl)-6-(4-methoxynaphthyl)-1,3,5-triazine; and benzophenone compounds, such as benzophenone, methyl o-benzoylbenzoate and 4-phenylbenzophenone.

In this photosensitive resin composition, a polymerization inhibitor, a solvent, a surface active agent, a sensitizer, an adhesive aid, or an inorganic filler, etc. can be appropriately contained, in addition to the resin (2), the crosslinking component (2) and the photoresponsive compound.

The method to form the coating film (a2) is the same as the aforesaid method to form the coating film (a1). The film thickness of the coating film (a2) is preferably 0.1 to 500 μm, more preferably 1 to 200 μm, still more preferably 10 to 100 μm.

The resin contained in the coating film (a2) is a resin contained as a constituent in the layer (2).

The coating film (a2) may be formed in contact with the upper surface of the coating film (a1), or may be formed on the coating film (a1) through a coating film that becomes an intermediate layer. As the coating film that becomes an intermediate layer, a coating film that is the same as the coating film (a2) can be used. The method to form the coating film that becomes an intermediate layer is the same as the method to form the coating film (a2).

Through the above steps, a film including the coating film (a1) and the coating film (a2) is formed. The film has a laminated structure consisting of the coating film (a1) and the coating film (a2) or a laminated structure consisting of the coating film (a1), the coating film (a2) and the intermediate layer.

In the step (I-3), the film is selectively exposed to light in such a manner that an opening is formed in an area of the film, said area corresponding to the electrode pad on the substrate.

In order to carry out selective light exposure, the resist is usually exposed to light through a desired photomask by the use of, for example, a contact aligner, a stepper or a scanner. As the exposure light, light having a wavelength of 200 to 500 nm (e.g., i-line (365 nm)) is used. The exposure varies depending upon the types of the components in the resist, the blending quantities, the thicknesses of the coating films, etc., but when i-line is used as the exposure light, the exposure is usually 1,000 to 100,000 mJ/m².

After the light exposure, heat treatment may be carried out. The conditions of the heat treatment after the light exposure are appropriately determined according to the types of the components in the resist, the blending quantities, the thicknesses of the coating films, etc., and the heat treatment is carried out usually at 70 to 180° C. for 1 to 60 minutes.

In the step (I-4), the film after the light exposure is developed to form an opening in an area in the film, said area corresponding to the electrode pad on the substrate. By virtue of this, a resist is obtained from the film, and a resist having openings formed like a pattern is formed on the substrate.

Examples of developing solutions used for the development include aqueous solutions of sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene and 1,5-diazabicyclo [4.3.0]-5-nonane. Moreover, aqueous solutions obtained by adding appropriate amounts of water-soluble organic solvents, such as methanol and ethanol, or surface active agents to the above aqueous solutions of alkalis can be also used as the developing solutions.

The developing time varies depending upon the types of the components in the film, the blending quantities, and the thicknesses of the coating films, etc., but it is usually 30 to 600 seconds. The developing method may be any of liquid supply method, dipping method, paddle method, spraying method, shower developing method and the like.

The resist obtained by the development may be further subjected to additional light exposure or heating to further cure the resist.

The post exposure can be carried out in the same manner as in the aforesaid light exposure. The exposure is not specifically restricted, but when a high-pressure mercury lamp is used, the exposure is preferably 100 to 2000 mJ/cm². For the heating, heat treatment has only to be carried out by the use of a heating device, such as a hot plate or an oven, at a given temperature, e.g., 60 to 100° C., for a given time, e.g., 5 to 30 minutes on a hot plate or 5 to 60 minutes in an oven.

The resist may be washed with running water or the like. Thereafter, the resist may be air-dried by using an air gun or the like or may be dried by heating with a hot plate, an oven or the like.

The step (II) of the second embodiment is the same as the step (II) of the first embodiment. Also in the second embodiment, a step (III) of peeling the resist may be carried out after the step (II).

### <Production Process for Laminate>

A first production process for a laminate according to the present invention comprises: a step (I) of forming an opening in a portion of a film provided on a first substrate having an electrode pad, said portion corresponding to the electrode pad on the substrate, and thereby forming a resist from the film on the substrate, a step (II) of filling the opening of the resist with molten solder to produce a solder electrode, and a step (IV) of laminating a second substrate having an electrode pad on the first substrate in such a manner that an electrical connection structure is formed between the electrode pad of the first substrate and the electrode pad of the second substrate through the solder electrode, and is characterized in that

the resist is composed of at least two layers each containing a resin as a constituent, and a layer (1) of the resist, said layer (1) being closest to the first substrate, does not substantially contain a component that thermally crosslinks the resin contained as a constituent in the layer (1) and a component that undergoes thermal self-crosslinking.

A second production process for a laminate according to the present invention is a production process for a laminate, comprising: a step (I) of forming an opening in a portion of a film provided on a first substrate having an electrode pad, said portion corresponding to the electrode pad on the substrate, and thereby forming a resist from the film on the substrate, a step (II) of filling the opening of the resist with molten solder to produce a solder electrode, a step (III) of peeling the resist from the first substrate, and a step (IV) of laminating a second substrate having an electrode pad on the first substrate in such a manner that an electrical connection structure is formed between the electrode pad of the first substrate and the electrode pad of the second substrate through the solder electrode,

wherein the resist is composed of at least two layers each containing a resin as a constituent, and a layer (1) of the resist, said layer (1) being closest to the substrate, does not substantially contain a component that thermally crosslinks the resin contained as a constituent in the layer (1) and a component that undergoes thermal self-crosslinking.

The steps (I) to (II) in the first and the second production processes for a laminate and the step (III) in the second production process for a laminate are substantially the same as the steps (I) to (III) in the aforesaid first embodiment of the production process for a solder electrode, respectively. That is to say, the first production process for a laminate is a process in which the step (IV) is carried out after the steps (1) to (II) in the aforesaid production process for a solder electrode, and the second production process for a laminate is a process in which the step (IV) is carried out after the steps (1) to (III) in the aforesaid production process for a solder electrode.

In the first and the second production processes for a laminate, the substrate in the aforesaid production process for a solder electrode corresponds to the first substrate.

In the first production process for a laminate, after the steps (I) to (II), a step (IV) of forming an electrical connection structure between the electrode pad of the first substrate and the electrode pad of the second substrate having an electrode pad through the solder electrode is carried out.

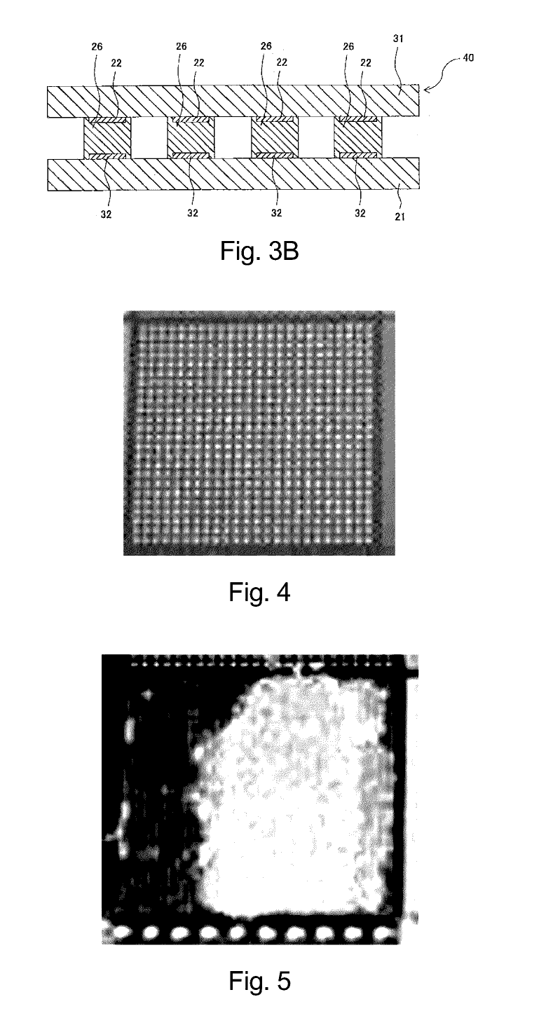

FIG. 3A shows a laminate 30 produced by the first production process for a laminate. The laminate 30 has an electrical connection structure that is formed by connecting an electrode pad 22 of the first substrate 21 and an electrode pad 32 of a second substrate 31 having an electrode pad 32 to each other through a solder electrode 26 produced by the aforesaid steps (I) to (II).

When the first substrate 21 and the second substrate 31 are placed in such a manner that their surfaces, on each of which an electrode pad has been formed, face each other, the electrode pad 32 of the second substrate 31 is provided at the position facing the electrode pad 22 of the first substrate 21. By bringing the electrode pad 32 of the second substrate 31 into contact with the solder electrode 26 and heating and/or pressure bonding them, the electrode pad 22 of the first substrate 21 and the electrode pad 32 of the second substrate 31 are electrically connected to each other through the solder electrode 26 to form an electrical connection structure, whereby a laminate 10 is obtained. The heating temperature is usually 100 to 300° C., and the pressure in the pressure bonding is usually 0.1 to 10 MPa.

In the second production process for a laminate, after the steps (I) to (III), a step (IV) of forming an electrical connection structure between the electrode pad of the first substrate and the electrode pad of the second substrate having an electrode pad through the solder electrode is carried out.

FIG. 3B shows a laminate 40 produced by the second production process for a laminate. The laminate 40 has an electrical connection structure that is formed by connecting an electrode pad 22 of the first substrate 21 and an electrode pad 32 of a second substrate 31 having an electrode pad 32 to each other through a solder electrode 26 produced by the aforesaid steps (I) to (III).

As described above, the laminate produced by the production process for a laminate according to the present invention may or may not have a resist between the first substrate and the second substrate. When the laminate has a resist like the laminate 30, the resist is used as an underfill.

Since the laminate produced by the production process for a laminate according to the present invention has an electrical connection structure that is suited to a purpose by virtue of the IMS method, selectivity of solder composition is widened, and therefore, the laminate can be applied to various electronic parts, such as semiconductor device, display device and power device.

The laminate produced by the production process for a laminate according to the present invention can be applied to various electronic parts, such as semiconductor device, display device and power device.

### EXAMPLES

The present invention is more specifically described hereinafter with reference to the following examples, but it should be construed that the present invention is in no way limited to those examples. In the description of the following examples, etc., the term “part(s)” is used to mean “part(s) by mass”.

### 1. Methods for Measuring Properties

Method for measuring weight-average molecular weight (Mw) of alkali-soluble resin (A)

Weight-average molecular weight (Mw) and number-average molecular weight (Mn) of an alkali-soluble resin (A) were measured by gel permeation chromatography under the following conditions.

Column: Columns of TSK-M and TSK2500 manufactured by Tosoh Corporation were connected in series.

Solvent: tetrahydrofuran

Temperature: 40° C.

Detection method: refractive index method

Standard substance: polystyrene

GPC device: manufactured by Tosoh Corporation, device name “HLC-8200-GPC”

### 2. Preparation of Resist-Forming Composition

### Synthesis Example 1

### Synthesis of Alkali-Soluble Resin

In a flask equipped with a dry ice/methanol refluxing device and purged with nitrogen, 5.0 g of 2,2′-azobisisobutyronitrile as a polymerization initiator and 90 g of diethylene glycol ethyl methyl ether as a polymerization solvent were placed, and they were stirred. In the resulting solution, 10 g of methacrylic acid, 15 g of p-isopropenylphenol, 25 g of tricycle [5.2.1.0^{2,6}] decanyl methacrylate, 20 g of isobornyl acrylate and 30 g of n-butyl acrylate were introduced, then stirring was initiated, and the temperature was raised up to 80° C. Thereafter, the system was heated at 80° C. for 6 hours.

After the heating was completed, the reaction product was dropwise added to a large amount of cyclohexane to perform coagulation. The coagulated substance was washed with water, then the coagulated substance was redissolved in tetrahydrofuran having the same mass as that of the coagulated substance, and thereafter, the resulting solution was dropwise added to a large amount of cyclohexane to perform coagulation again. These redissolving and coagulation operations were carried out three times in total, and then, the resulting coagulated substance was vacuum dried at 40° C. for 48 hours to obtain an alkali-soluble resin. The weight-average molecular weight of the alkali-soluble resin was 10,000.

### Preparation Example 1

### Preparation of Photosensitive Resin Composition 1

100 Parts of the alkali-soluble resin synthesized in Synthesis Example 1, 50 parts of polyester acrylate (trade name “ARONIX M-8060”, available from Toagosei Co., Ltd.), 5 parts of trimethylolpropane triacrylate, 4 parts of diphenyl (2,4,6-trimethylbenzoyl)phosphine oxide (trade name “LUCIRIN TPO”, available from BASF), 0.4 part of a compound represented by the following formula (1), 100 parts of propylene glycol monomethyl ether acetate (E-1) and 0.1 part of a fluorine-based surface active agent (trade name “Futergent FTX-218”, available from NEOS COMPANY LIMITED) were mixed and stirred to obtain a homogeneous solution. This solution was filtered through a capsule filter having a pore diameter of 10 μm to prepare a photosensitive resin composition 1.

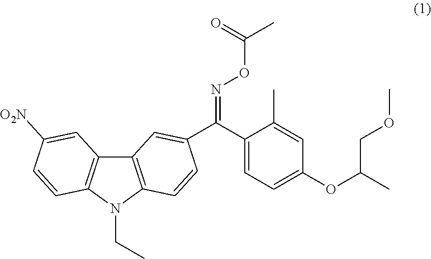 [SMILES: CCn1c2ccc(/C(=N/OC(C)=O)c3ccc(OC(C)COC)cc3C)cc2c2cc([N+](=O)[O-])ccc21]

### Preparation Example 2

### Preparation of Photosensitive Resin Composition 1

100 Parts of the alkali-soluble resin synthesized in Synthesis Example 1, 50 parts of polyester acrylate (trade name “ARONIX M-8060”, available from Toagosei Co., Ltd.), 4 parts of diphenyl(2,4,6-trimethylbenzoyl)phosphine oxide (trade name “LUCIRIN TPO”, available from BASF), 19 parts of 2,2-dimethoxy-1,2-diphenylethane-1-one (trade name “IRGACURE 651”, available from BASF), 80 parts of propylene glycol monomethyl ether acetate and 0.1 part of a fluorine-based surface active agent (trade name “Futergent FTX-218”, available from NEOS COMPANY LIMITED) were mixed and stirred to obtain a homogeneous solution. This solution was filtered through a capsule filter having a pore diameter of 10 μm to prepare a photosensitive resin composition 2.

### Synthesis Example 2

### Synthesis of Resin 1

A flask equipped with a dry ice/methanol refluxing device and a thermometer was purged with nitrogen. Thereafter, in this flask, 90 g of N-(3,5-dimethyl-4-hydroxybenzyl)acrylamide, 10 g of styrene and 300 g of methanol were placed, and they were stirred. Subsequently, 4 g of 2,2′-azobisisobutyronitrile was added, and under reflux of methanol, polymerization was carried out for 8 hours while stirring. After the polymerization was completed, the system was cooled down to room temperature, and the polymer solution was introduced into a large amount of water to coagulate the polymer produced. Subsequently, operations of redissolving the polymer in tetrahydrofuran and then coagulating the polymer in a large amount of hexane again were repeated three times. The coagulated substance obtained by these operations was dried to obtain a resin 1.

### Preparation Example 3

### Preparation of Resin Composition 1

100 Parts of the resin 1 synthesized in Synthesis Example 2, 0.1 part of a fluorine-based surface active agent (trade name “Futergent FTX-218”, available from NEOS COMPANY LIMITED) and 900 parts of propylene glycol monomethyl ether acetate were mixed and stirred to obtain a homogeneous solution. This solution was filtered through a capsule filter having a pore diameter of 10 μm to prepare a resin composition 1.

### 3. Production of Solder Electrode

### Example 1

To a substrate having plural copper electrode pads on a silicon plate, the resin composition 1 prepared in Preparation Example 3 was applied by the use of a spin coater, and it was heated on a hot plate at 110° C. for 3 minutes to form a coating film (a1-1) having a thickness of 1 μm. Then, onto the coating film (a1-1), the photosensitive resin composition 1 prepared in Preparation Example 1 was applied by the use of a spin coater, and it was heated on a hot plate at 120° C. for 5 minutes to form a coating film (a2-1) having a thickness of 55 μm. Subsequently, light exposure (wavelength: 420 nm, irradiation intensity: 300 mJ/cm²) was carried out through a pattern mask by the use of an aligner (manufactured by Suss, model “MA-200”). After the light exposure, the coating film (a1-1) and the coating film (a2-1) were brought into contact with a 2.38 mass % tetramethylammonium hydroxide aqueous solution for 240 seconds, then the coating films were washed with running water, and they were developed. Subsequently, the substrate with the coating films was heated on a hot plate at 200° C. for 10 minutes in a flow of nitrogen to form a resist holding substrate having a large number of openings. When observation by an electron microscope was carried out, the open tip of each opening had a circular shape having a diameter of 50 μm, and the depth of each opening was 50 μm. The distance between adjacent openings was 50 μm.

When the total content of polyester acrylate and trimethylolpropane triacrylate in the photosensitive resin composition 1 prepared in Preparation Example 1 was 100% by mass, the total content of polyester acrylate and trimethylolpropane triacrylate in the coating film (a2-1) was 58 to 65% by mass.

The resist holding substrate having openings was immersed in a 1 mass % sulfuric acid aqueous solution at 23° C. for 1 minute, then washed with water and dried. Into the openings of the substrate after drying, molten solder (obtained by melting “SAC305” (trade name, available from Senju Metal Industry Co., Ltd.) at 250° C.) was rubbed over a period of 10 minutes. Thereafter, the resist holding substrate was immersed in a solution of dimethyl sulfoxide/tetramethylammonium hydroxide/water (90/3/7 by mass) at 50° C. for 20 minutes to peel the resist, then washed with water and dried to produce solder electrodes.

When the resulting solder electrodes were observed by an electron microscope, solders having been formed like a pattern each had a columnar shape having a diameter of 50 μm and a height of 50 μm. Between adjacent solders, any solder was not present. An electron microscopic image of the solder electrodes given after peeling of the resist is shown in FIG. 4.

### Example 2

A resist holding substrate having a large number of openings was formed by the same operations as in Example 1, except that the film thickness of the coating film (a1-1) was changed to 0.5 μm. When observation by an electron microscope was carried out, the open tip of each opening had a circular shape having a diameter of 50 μm, and the depth of each opening was 50 μm. The distance between adjacent openings was 50 μm.

The resist holding substrate having openings was immersed in a 1 mass % sulfuric acid aqueous solution at 23° C. for 1 minute, then washed with water and dried. Into the openings of the substrate after drying, molten solder (obtained by melting “SAC305” (trade name, available from Senju Metal Industry Co., Ltd.) at 250° C.) was rubbed over a period of 10 minutes. Thereafter, the resist holding substrate was immersed in a solution of dimethyl sulfoxide/tetramethylammonium hydroxide/water (90/3/7 by mass) at 50° C. for 20 minutes to peel the resist, then washed with water and dried to produce solder electrodes.

When the resulting solder electrodes were observed by an electron microscope, solders having been formed like a pattern each had a columnar shape having a diameter of 50 μm and a height of 50 μm. Between adjacent solders, any solder was not present.

### Comparative Example 1

The same operations as in Example 1 were carried out, except that the photosensitive resin composition 2 prepared in Preparation Example 2 was used instead of the resin composition 1.

When the resulting solder pattern was observed by an electron microscope, solders having been formed like a pattern each had a columnar shape having a diameter of 50 μm and a height of 50 μm, but between adjacent solders, solder was present. It is thought that when the molten solder of 250° C. was rubbed into the openings, the resist was peeled from the substrate, and the molten solder penetrated between the sputtered copper film and the resist.

### Comparative Example 2

To a substrate having plural copper electrode pads on a silicon plate, the photosensitive resin composition 1 prepared in Preparation Example 1 was applied by the use of a spin coater, and it was heated on a hot plate at 120° C. for 5 minutes to form a coating film (a1-1) having a thickness of 55 μm. Subsequently, light exposure (wavelength: 420 nm, irradiation intensity: 300 mJ/cm²) was carried out through a pattern mask by the use of an aligner (manufactured by Suss, model “MA-200”). After the light exposure, the coating film (a1-1) was brought into contact with a 2.38 mass % tetramethylammonium hydroxide aqueous solution for 240 seconds, and the coating film was washed with running water and developed. Subsequently, the substrate with the coating film was heated on a hot plate at 200° C. for 10 minutes in a flow of nitrogen to form a resist holding substrate having a large number of openings. When observation by an electron microscope was carried out, the open tip of each opening had a circular shape having a diameter of 50 μm, and the depth of each opening was 50 μm. The distance between adjacent openings was 50 μm.

The resist holding substrate having openings was immersed in a 1 mass % sulfuric acid aqueous solution at 23° C. for 1 minute, then washed with water and dried. Into the openings of the substrate after drying, molten solder (obtained by melting “SAC305” (trade name, available from Senju Metal Industry Co., Ltd.) at 250° C.) was rubbed over a period of 10 minutes. Thereafter, the resist holding substrate was immersed in a solution of dimethyl sulfoxide/tetramethylammonium hydroxide/water (90/3/7 by mass) at 50° C. for 20 minutes to peel the resist, then washed with water and dried to produce solder electrodes.

When the resulting solder electrodes were observed by an electron microscope, solders having been formed like a pattern each had a columnar shape having a diameter of 50 μm and a height of 50 μm, but between adjacent solders, solder was present. It is thought that when the molten solder of 250° C. was rubbed into the openings, the resist was peeled from the substrate, and the molten solder penetrated between the sputtered copper film and the resist. An electron microscopic image of the solder electrodes given after peeling of the resist is shown in FIG. 5.

### 4. Evaluation of Adhesion Between Substrate and Resist

### Experimental Example 1

To a substrate obtained by providing a sputtered copper film (film thickness of sputtered copper film: 0.6 μm) on a silicon plate, the resin composition 1 prepared in Preparation Example 3 was applied by the use of a spin coater, and it was heated on a hot plate at 110° C. for 3 minutes to form a coating film (a1-1) having a thickness of 1 μm. Then, onto the coating film (a1-1), the photosensitive resin composition 1 prepared in Preparation Example 1 was applied by the use of a spin coater, and it was heated on a hot plate at 120° C. for 5 minutes to form a coating film (a2-1) having a thickness of 55 μm. Thereafter, the substrate with the coating films was heated on a hot plate at 200° C. for 10 minutes to prepare a coating film for adhesion evaluation on the substrate.

The adhesion between the resulting coating film for adhesion evaluation and the sputtered copper film was evaluated by a pin test. The pin test was carried out using a pin equipped with a disc part having a diameter of 4 mm and a spindle, which was a stud pin with epoxy adhesive (pin number “901160”, manufactured by PHOTOTECHNICA CORPORATION), as shown in FIG. 2. As shown in FIG. 2, the pin 1 was adhesive-bonded to the coating film 3 for adhesion evaluation formed on the substrate obtained by providing a sputtered copper film 4 on a silicon plate 5, then the substrate was fixed, and the pin 1 was pulled in the perpendicular direction to the coating film for adhesion evaluation at a rate of 4.68 to 5.85 mm/min.

As a result, separation between the coating film for adhesion evaluation and the sputtered copper film did not take place, but separation between the coating film for adhesion evaluation and the pin took place. That is to say, it becomes apparent that the adhesive strength between the coating film for adhesion evaluation and the sputtered copper film is higher than the adhesive strength between the coating film for adhesion evaluation and the epoxy-based adhesive, and the coating film for adhesion evaluation has excellent adhesion to the sputtered copper film.

### Experimental Example 2

Adhesion between the resulting coating film and the sputtered copper film was evaluated in the same manner as in Experimental Example 1, except that the photosensitive resin composition 2 prepared in Preparation Example 2 was used instead of the resin composition 1.

As a result, separation between the coating film for adhesion evaluation and the pin did not take place, but separation between the coating film for adhesion evaluation and the sputtered copper film took place. That is to say, it becomes apparent that the adhesive strength between the coating film for adhesion evaluation and the sputtered copper film is lower than the adhesive strength between the coating film for adhesion evaluation and the epoxy-based adhesive, and the coating film for adhesion evaluation has poor adhesion to the sputtered copper film.

### Experimental Example 3

To a substrate obtained by providing a sputtered copper film (film thickness of sputtered copper film: 0.6 μm) on a silicon plate, the photosensitive resin composition 1 prepared in Preparation Example 1 was applied by the use of a spin coater, and it was heated on a hot plate at 120° C. for 5 minutes to form a coating film (a1-1) having a thickness of 55 μm. Thereafter, the substrate with the coating film was heated on a hot plate at 250° C. for 10 minutes to prepare a coating film for adhesion evaluation on the substrate.

Adhesion between the resulting coating film for adhesion evaluation and the sputtered copper film was evaluated by a pin test similarly to Experimental Example 1.

As a result, separation between the coating film for adhesion evaluation and the pin did not take place, but separation between the coating film for adhesion evaluation and the sputtered copper film took place. That is to say, it becomes apparent that the adhesive strength between the coating film for adhesion evaluation and the sputtered copper film is lower than the adhesive strength between the coating film for adhesion evaluation and the epoxy-based adhesive, and the coating film for adhesion evaluation has poor adhesion to the sputtered copper film.

### Experimental Example 4

A coating film for adhesion evaluation was prepared on a substrate by the same operations as in Experimental Example 1, except that the film thickness of the coating film (a1-1) was changed to 0.5 μm.

As a result, separation between the coating film for adhesion evaluation and the sputtered copper film did not take place, but separation between the coating film for adhesion evaluation and the pin took place. That is to say, it becomes apparent that the adhesive strength between the coating film for adhesion evaluation and the sputtered copper film is higher than the adhesive strength between the coating film for adhesion evaluation and the epoxy-based adhesive, and the coating film for adhesion evaluation has excellent adhesion to the sputtered copper film.

### INDUSTRIAL APPLICABILITY

By the process for forming a solder electrode according to the present invention, as described above, a desired solder electrode can be surely formed, and when the process is applied to, for example, an IMS method, preferred formation of a bump becomes possible. On this account, by utilizing the process for forming a solder electrode according to the present invention, electronic parts having excellent solder electrodes can be provided.

1. A production process for a solder electrode, comprising:
a step (I) of forming an opening in a portion of a film provided on a substrate having an electrode pad, said portion corresponding to the electrode pad on the substrate, and thereby forming a resist from the film on the substrate; and
a step (II) of filling the opening of the resist with molten solder,
wherein the resist is composed of at least two layers each containing a resin as a constituent, and a layer (1) of the resist, said layer (1) being closest to the substrate, does not substantially contain a component that thermally crosslinks the resin contained as a constituent in the layer (1) and a component that undergoes thermal self-crosslinking.

2. The production process as claimed in claim 1, wherein a layer (2) in the resist, said layer (2) being farthest from the substrate, contains at least one component selected from a component that thermally crosslinks the resin contained as a constituent in the layer (2) and a component that undergoes thermal self-crosslinking.

3. The production process as claimed in claim 1, wherein a thickness of the layer (1) closest to the substrate is 0.001 to 0.9 time a thickness of the resist.

4. A production process for a solder electrode, comprising:
a step (I), having a step (I-1) of forming a coating film (a1) obtained from a resin composition on a substrate having an electrode pad, a step (I-2) of forming a coating film (a2) obtained from a photosensitive resin composition on the coating film (a1) to form a film including the coating film (a1) and the coating film (a2), a step (I-3) of selectively exposing the film to light in such a manner that an opening is formed in a portion of the film, said portion corresponding to the electrode pad on the substrate, and a step (I-4) of developing the film to form an opening in an area of the film, said area corresponding to the electrode pad on the substrate, and thereby forming a resist from the film on the substrate; and
a step (II) of filling the opening of the resist with molten solder,
wherein the resin composition does not substantially contain a component that thermally crosslinks a resin contained in the resin composition and a component that undergoes thermal self-crosslinking, and the photosensitive resin composition contains at least one component selected from a component that thermally crosslinks a resin contained in the photosensitive resin composition and a component that undergoes thermal self-crosslinking.

5. The production process as claimed in claim 1, further comprising a step (III) of peeling the resist after the step (II).

6. The production process as claimed in claim 4, further comprising a step (III) of peeling the resist after the step (II).

7. An electronic part having a solder electrode formed by the production process as claimed in claim 1.

8. An electronic part having a solder electrode formed by the production process as claimed in claim 4.

9. A production process for a laminate, comprising:
a step (I) of forming an opening in a portion of a film provided on a first substrate having a first electrode pad, said portion corresponding to the first electrode pad on the first substrate, and thereby forming a resist from the film on the first substrate;
a step (II) of filling the opening of the resist with molten solder to produce a solder electrode; and
a step (IV) of laminating a second substrate having a second electrode pad on the first substrate in such a manner that an electrical connection structure is formed between the first electrode pad of the first substrate and the second electrode pad of the second substrate through the solder electrode,
wherein the resist is composed of at least two layers each containing a resin as a constituent, and a layer (1) of the resist, said layer (1) being closest to the first substrate, does not substantially contain a component that thermally crosslinks the resin contained as a constituent in the layer (1) and a component that undergoes thermal self-crosslinking.

10. The production process as claimed in claim 9, further comprising, after the step (II) but before the step (IV), a step (III) of peeling the resist from the first substrate.

11. A laminate produced by the production process as claimed in claim 9.

12. A laminate produced by the production process as claimed in claim 10.

13. An electronic part having the laminate as claimed in claim 11.

14. An electronic part having the laminate as claimed in claim 12.
